(19) United States
(12) Patent Application Publication
(10) Pub. No.: US 2023/0378932 A1
(43) Pub. Date: Nov. 23, 2023

(54) ACOUSTIC WAVE DEVICE

(71) Applicant: Murata Manufacturing Co., Ltd., Nagaokakyo-shi (JP)

(72) Inventor: Takuro OKADA, Nagaokakyo-shi (JP)

(21) Appl. No.: 18/229,203

(22) Filed: Aug. 2, 2023

Related U.S. Application Data
(63) Continuation of application No. PCT/JP2022/017509, filed on Apr. 11, 2022.

(30) Foreign Application Priority Data
Apr. 19, 2021 (JP) 2021-070466

(51) Int. Cl. H03H 9/02; H03H 9/145; H03H 9/25

(52) U.S. Cl. CPC H03H 9/02866; H03H 9/02559; H03H 9/02889; H03H 9/02992; H03H 9/1457; H03H 9/25

(57) ABSTRACT

An acoustic wave device includes a piezoelectric film directly or indirectly provided on a high acoustic-velocity material layer, and an IDT electrode on the piezoelectric film. A dielectric film is provided between the IDT electrode and the piezoelectric film. The IDT electrode includes a central region and first and second low acoustic-velocity regions on both respective sides in an extending direction of first and second electrode fingers in an intersecting region where the first and second electrode fingers overlap with each other. A film thickness of the dielectric film is set in a range shown in Table 1.

### CROSS REFERENCE TO RELATED APPLICATIONS

This application claims the benefit of priority to Japanese Patent Application No. 2021-070466 filed on Apr. 19, 2021 and is a Continuation application of PCT Application No. PCT/JP2022/017509 filed on Apr. 11, 2022. The entire contents of each application are hereby incorporated herein by reference.

### BACKGROUND OF THE INVENTION

### 1. Field of the Invention

The present invention relates to an acoustic wave device in which a dielectric film is laminated between an IDT electrode and a piezoelectric film.

### 2. Description of the Related Art

In the acoustic wave device described in International Publication No. 2018/146883, a high acoustic-velocity material layer, a low acoustic-velocity film, and a piezoelectric film are laminated on a support substrate. Further, a dielectric film is laminated on the piezoelectric film and an IDT electrode is provided on the dielectric film.

The structure including the high acoustic-velocity material layer and the low acoustic-velocity film can increase a Q value.

In acoustic wave devices, transverse modes that are spurious to acoustic waves used sometimes occur. As a structure for suppressing such a transverse mode, a structure is known in which a low acoustic-velocity region, in which an acoustic velocity is lower than that in a central region, is provided in an intersecting region of an IDT electrode.

However, when the low acoustic-velocity region is provided in an acoustic wave device such as the one described in International Publication No. 2018/146883, it becomes difficult to effectively suppress transverse modes and characteristics may deteriorate.

### SUMMARY OF THE INVENTION

Preferred embodiments of the present invention provide acoustic wave devices each with characteristics that are less likely to deteriorate.

An acoustic wave device according to a preferred embodiment of the present invention includes a high acoustic-velocity material layer made of a high acoustic-velocity material, a piezoelectric film directly or indirectly provided on the high acoustic-velocity material layer, and an IDT electrode on the piezoelectric film. The high acoustic-velocity material is a material in which an acoustic velocity of a bulk wave propagating therethrough is higher than an acoustic velocity of an acoustic wave propagating through the piezoelectric film. The acoustic wave device further includes a dielectric film between the IDT electrode and the piezoelectric film. The IDT electrode includes a first electrode finger and a second electrode finger that are interdigitated. A direction orthogonal or substantially orthogonal to an extending direction of the first electrode finger and the second electrode finger is an acoustic wave propagating direction. A region in which the first electrode finger and the second electrode finger overlap with each other when viewed in the acoustic wave propagating direction is an intersecting region. The intersecting region includes a central region, which is positioned in a center in the extending direction of the first electrode finger and the second electrode finger, and first and second low acoustic-velocity regions provided on both respective sides of the central region in the extending direction of the first electrode finger and the second electrode finger. The dielectric film is made of silicon nitride, silicon oxide, tantalum pentoxide, alumina, titanium oxide, or amorphous silicon. A film thickness of the dielectric film is set in a range shown in Table 1 below depending on a material of the dielectric film:

TABLE 1

| Material of dielectric film | Film thickness range (Unit: %) |
|---|---|
| Silicon nitride | Greater than 0, 3.125 or less |
| Silicon oxide | From 0.5 to 3.5 inclusive |
| Tantalum pentoxide | Greater than 0, 3.125 or less |
| Alumina | Greater than 0, 4 or less |
| Titanium oxide | From 0.005 to 1.5 inclusive |
| Amorphous silicon | From 0.005 to 10.25 inclusive. |

The film thickness in Table 1 is a film thickness (%) normalized by a wavelength A determined based on an electrode finger pitch of the IDT electrode.

According to preferred embodiments of the present invention, acoustic wave devices each with characteristics that are less likely to deteriorate are able to be provided.

The above and other elements, features, steps, characteristics and advantages of the present invention will become more apparent from the following detailed description of the preferred embodiments with reference to the attached drawings.

### BRIEF DESCRIPTION OF THE DRAWINGS

FIGS. 1A and 1B are front sectional views of an acoustic wave device according to a first preferred embodiment of the present invention.

FIG. 2 is a schematic plan view illustrating an electrode structure of the acoustic wave device according to the first preferred embodiment of the present invention.

FIG. 3 is a plan view for explaining an IDT electrode, and a central region and a low acoustic-velocity region in the acoustic wave device according to the first preferred embodiment of the present invention.

FIG. 4 is a diagram illustrating a relationship between dielectric film thickness (wavelength normalized film thickness (%)) and an acoustic velocity ratio in the acoustic wave device according to the first preferred embodiment of the present invention.

FIG. 5 is a diagram illustrating a relationship between dielectric film thickness and normalized acoustic velocities in the central region and the low acoustic-velocity region of the IDT electrode, in the first preferred embodiment of the present invention.

FIG. 6 is a diagram illustrating a relationship between dielectric film thickness and inclinations of change amounts of acoustic velocities in the central region and the low acoustic-velocity region of the IDT electrode, in the first preferred embodiment of the present invention.

FIG. 7 is a diagram illustrating a relationship between dielectric film thickness of a dielectric film which is a silicon oxide film and an acoustic velocity ratio.

FIG. 8 is a diagram illustrating a relationship between dielectric film thickness of a dielectric film which is a tantalum pentoxide film and an acoustic velocity ratio.

FIG. 9 is a diagram illustrating a relationship between dielectric film thickness of a dielectric film which is an alumina film and an acoustic velocity ratio.

FIG. 10 is a diagram illustrating a relationship between dielectric film thickness of a dielectric film which is a titanium oxide film and an acoustic velocity ratio.

FIG. 11 is a diagram illustrating a relationship between dielectric film thickness of a dielectric film which is an amorphous silicon film and an acoustic velocity ratio.

FIG. 12 is a plan view for explaining an IDT electrode of an acoustic wave device according to a second preferred embodiment of the present invention.

FIG. 13 is a plan view for explaining an IDT electrode of an acoustic wave device according to a third preferred embodiment of the present invention.

FIG. 14 is a plan view for explaining an IDT electrode of an acoustic wave device according to a fourth preferred embodiment of the present invention.

FIG. 15 is a plan view for explaining an IDT electrode of an acoustic wave device according to a fifth preferred embodiment of the present invention.

FIG. 16 is a plan view for explaining an IDT electrode of an acoustic wave device according to a sixth preferred embodiment of the present invention.

FIG. 17 is a front sectional view of an acoustic wave device according to a seventh preferred embodiment of the present invention.

### DETAILED DESCRIPTION OF THE PREFERRED EMBODIMENTS

The present invention will be clarified below by describing preferred embodiments of the present invention with reference to the accompanying drawings.

Each of the preferred embodiments described in the present specification is exemplary and configurations can be partially exchanged or combined with each other between different preferred embodiments.

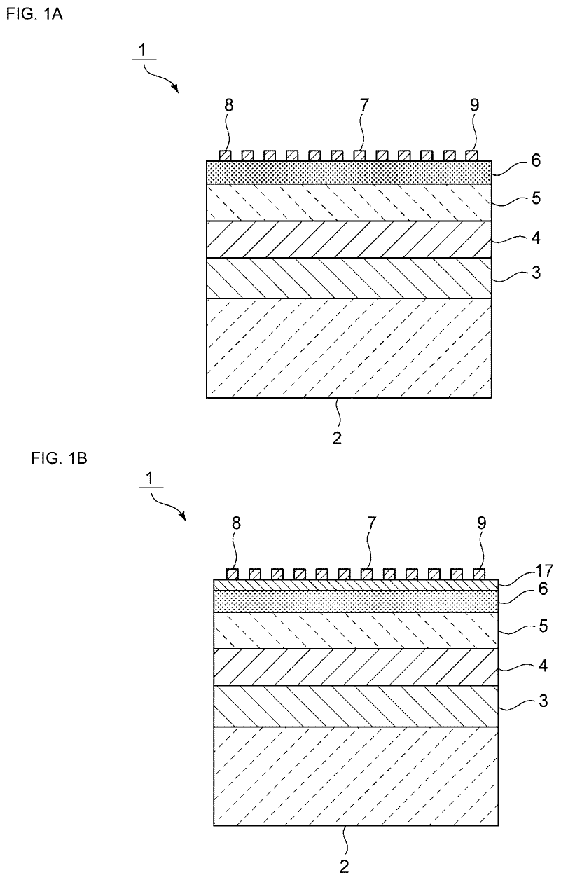

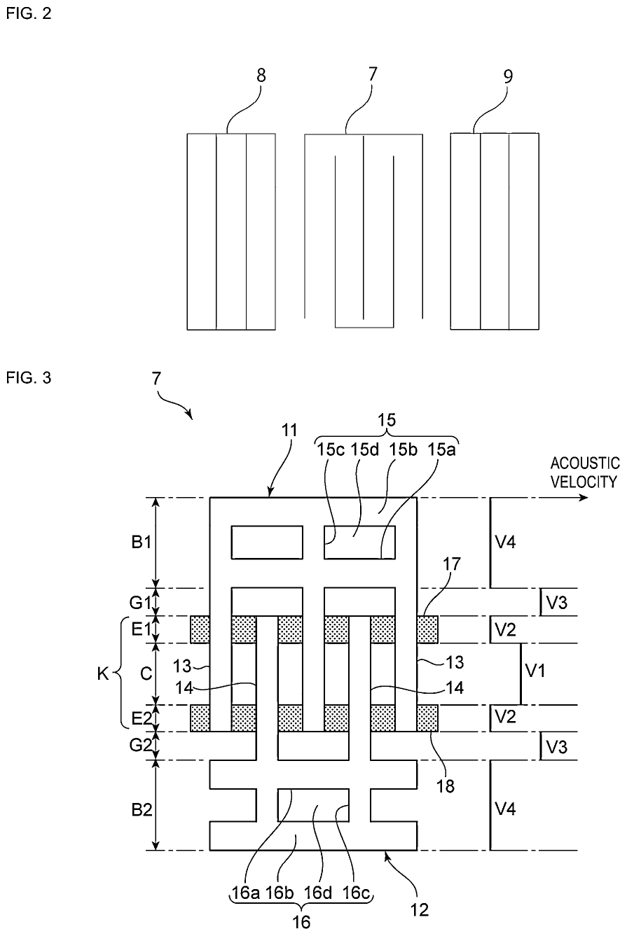

FIGS. 1A and 1B are front sectional views of an acoustic wave device according to a first preferred embodiment of the present invention, and FIG. 2 is a schematic plan view illustrating an electrode structure of the acoustic wave device. FIG. 1A illustrates a cross section at the center of an intersecting region of the IDT electrode. FIG. 1B illustrates a cross section through a first low acoustic-velocity region E1, which will be described later.

In an acoustic wave device 1, a high acoustic-velocity material layer 3, a low acoustic-velocity film 4, and a piezoelectric film 5 are laminated on a support substrate 2. That is, the support substrate 2 is laminated on a surface, which is opposite to a surface on a piezoelectric film 5 side, of the high acoustic-velocity material layer 3. The support substrate 2 is made of Si, for example, but the material of the support substrate 2 is not particularly limited. Various insulators and semiconductors can be used as the material of the support substrate 2.

The high acoustic-velocity material layer 3 is made of a high acoustic-velocity material. The high acoustic-velocity material is a material in which an acoustic velocity of a bulk wave propagating through this material is higher than an acoustic velocity of an acoustic wave propagating through the piezoelectric film 5. Examples of the high acoustic-velocity material may include various materials such as aluminum oxide, silicon carbide, silicon nitride, silicon oxynitride, silicon, sapphire, lithium tantalate, lithium niobate, crystal, alumina, zirconia, cordierite, mullite, steatite, forsterite, magnesia, diamond-like carbon (DLC) film, or diamond, a medium including the above-described material as a main component, and a medium including a mixture of the above-described materials as a main component. In the present preferred embodiment, the high acoustic-velocity material layer 3 is made of silicon nitride, for example.

The low acoustic-velocity film 4 is made of a low acoustic-velocity material. The low acoustic-velocity material is a material in which an acoustic velocity of a bulk wave propagating through this material is lower than an acoustic velocity of an acoustic velocity of a bulk wave propagating through the piezoelectric film 5. Examples of the low acoustic-velocity material may include various materials such as silicon oxide, glass, silicon oxynitride, tantalum oxide, a compound obtained by adding fluorine, carbon, boron, hydrogen, or a silanol group to silicon oxide, and a medium including the above-described material as a main component. In the present preferred embodiment, the low acoustic-velocity film 4 is made of silicon oxide, for example.

The piezoelectric film 5 is made of lithium tantalate, for example. However, the piezoelectric film 5 may be made of other piezoelectric single crystals such as lithium niobate, for example.

The piezoelectric film 5 is laminated on the high acoustic-velocity material layer 3 and the low acoustic-velocity film 4 and therefore, a Q value can be increased in the acoustic wave device 1.

Meanwhile, a dielectric film 6 is laminated on the piezoelectric film 5. The dielectric film 6 is made of, for example, silicon nitride (SiN) in the present preferred embodiment. However, the material of the dielectric film 6 is not limited to silicon nitride and may be, for example, silicon oxide, alumina, tantalum pentoxide, amorphous silicon, titanium oxide, or the like.

The IDT electrode 7 and reflectors 8 and 9 are provided on the dielectric film 6.

The IDT electrode 7 will be described in detail with reference to FIG. 3. FIG. 3 is a plan view for explaining the IDT electrode 7, and a central region and a low acoustic-velocity region.

The IDT electrode 7 includes a first comb electrode 11 and a second comb electrode 12. The first comb electrode 11 includes a plurality of first electrode fingers 13. The second comb electrode 12 includes a plurality of second electrode fingers 14. The first electrode fingers 13 and the second electrode fingers 14 are interdigitated. A direction orthogonal or substantially orthogonal to an extending direction of the first electrode fingers 13 and the second electrode fingers 14 is an acoustic wave propagating direction. A region in which the first electrode fingers 13 and the second electrode fingers 14 overlap with each other when viewed in the acoustic wave propagating direction is an intersecting region K. The intersecting region K includes a central region C and first and second low acoustic-velocity regions E1 and E2. The central region C is positioned at the center in the extending direction of the first and second electrode fingers 13 and 14. The first and second low acoustic-velocity regions E1 and E2 are provided on both respective sides of the central region C in the extending direction of the first and second electrode fingers 13 and 14.

In the first and second low acoustic-velocity regions E1 and E2, dielectric films 17 and 18 are laminated between the first and second electrode fingers 13 and 14 and the dielectric film 6. This lowers acoustic velocities in the first and second low acoustic-velocity regions E1 and E2. The dielectric films 17 and 18 are made of, for example, silicon oxide, but other dielectrics may be used.

The first and second low acoustic-velocity regions E1 and E2 are regions in which an acoustic velocity is lower than that in the central region C. FIG. 3 schematically illustrates an acoustic velocity of each region on the right side. An acoustic velocity V1 in the central region C is higher than an acoustic velocity V2 in the first and second low acoustic-velocity regions E1 and E2.

In the first comb electrode 11, one end of each of the plurality of first electrode fingers 13 is connected to a first busbar 15. In the second comb electrode 12, one end of each of the plurality of second electrode fingers 14 is connected to a second busbar 16.

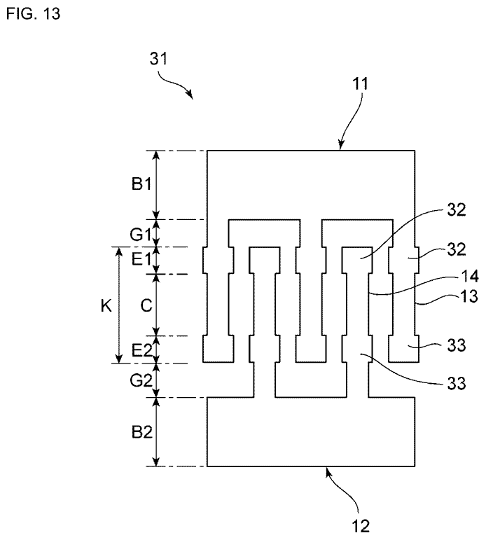

The first busbar 15 includes an inner busbar 15a, an outer busbar 15b, and a coupling portion 15c, which couples the inner busbar 15a with the outer busbar 15b. Further, a plurality of openings 15d are provided along the acoustic wave propagating direction. In a similar manner, the second busbar 16 also includes an inner busbar 16a, an outer busbar 16b, a coupling portion 16c, and openings 16d. However, the first busbar 15 and the second busbar 16 are not limitedly structured to include inner busbars, outer busbars, and openings, and may be busbars that do not include these, such as busbars illustrated in FIGS. 13 to 16.

In the IDT electrode 7, first and second gap regions G1 and G2 are positioned on respective outer sides, in the extending direction of the first and second electrode fingers 13 and 14, of the first and second low acoustic-velocity regions E1 and E2. Further, first and second busbar regions B1 and B2 are positioned on respective outer sides, in the extending direction of the first and second electrode fingers 13 and 14, of the first and second gap regions G1 and G2. An acoustic velocity in the first and second gap regions G1 and G2 is V3 and the acoustic velocity V3 is higher than the acoustic velocity V2 in the first and second low acoustic-velocity regions E1 and E2. Further, an acoustic velocity in the first and second busbar regions B1 and B2 is V4 and the acoustic velocity V4 is lower than the acoustic velocity V3 in the first and second gap regions G1 and G2.

V1>V2 and V3>V2 are satisfied and therefore, reduction or prevention of transverse modes can be achieved. Such a transverse mode reduction or prevention structure utilizing an acoustic velocity difference has been conventionally known.

In order to effectively reduce or prevent the above-described transverse modes, an acoustic velocity difference needs to be increased between the acoustic velocity V1 in the central region C and the acoustic velocity V2 in the first and second low acoustic-velocity regions E1 and E2.

The inventor of preferred embodiments of the present application has discovered that a sufficient acoustic velocity difference, described above, sometimes cannot be obtained and accordingly transverse modes sometimes cannot be sufficiently reduced or prevented in the acoustic wave device 1 having the laminated structure illustrated in FIGS. 1A and 1B. It has also been discovered that the above-described acoustic velocity difference changes depending on the film thickness of the dielectric film 6 and a transverse mode reduction or prevention effect changes.

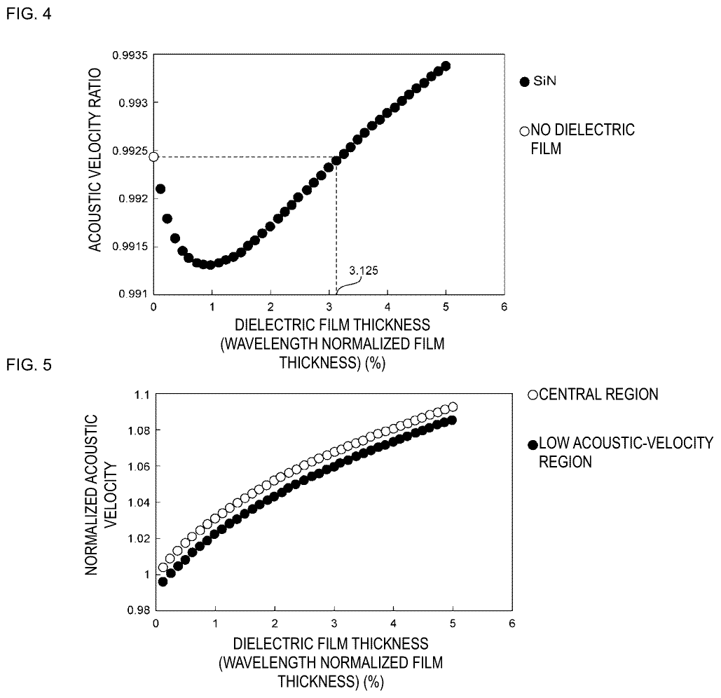

FIG. 4 is a diagram illustrating a relationship between the film thickness of the dielectric film 6 (wavelength normalized film thickness (%)) and an acoustic velocity ratio in the acoustic wave device according to the first preferred embodiment of the present invention. The wavelength normalized film thickness is film thickness (%) normalized by a wavelength A determined based on an electrode finger pitch of an IDT electrode. The acoustic velocity ratio is a ratio of the acoustic velocity in the first and second low acoustic-velocity regions E1 and E2 with respect to the acoustic velocity in the central region C.

As is clear from FIG. 4, when the film thickness of the dielectric film 6, that is, for example, a silicon nitride (SiN) film changes, the above-described acoustic velocity ratio changes. Especially, a sufficient acoustic velocity ratio can be obtained when the film thickness of the dielectric film 6 is, for example, greater than 0% and is less than or equal to about 3.125%, compared to when the dielectric film 6 is not provided, that is, when the film thickness of the dielectric film 6 is 0%. Accordingly, for example, when a silicon nitride film is used as the dielectric film 6, transverse modes can be effectively reduced or prevented if the film thickness of the dielectric film 6 is greater than 0% and is less than or equal to about 3.125%.

The reason why an acoustic velocity ratio changes depending on the film thickness of the dielectric film 6 as described above is as follows.

FIG. 5 is a diagram illustrating a relationship between film thickness of a dielectric film which is made of, for example, silicon nitride and normalized acoustic velocities in a central region and a low acoustic-velocity region of an IDT electrode. In FIG. 5, ● denotes the normalized acoustic velocity in the low acoustic-velocity region and ◯ denotes the normalized acoustic velocity in the central region. The normalized acoustic velocity here indicates a value obtained by dividing a frequency at each film thickness by a frequency in the central region obtained when no dielectric film is provided.

As can be seen from FIG. 5, the normalized acoustic velocities increase as the film thickness of the dielectric film increases, but the trend is slightly different between the low acoustic-velocity region and the central region.

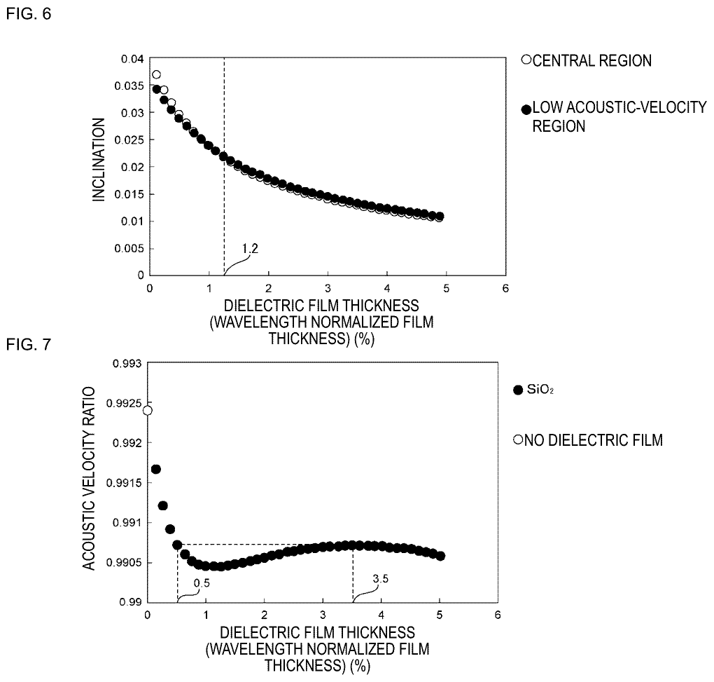

FIG. 6 is a diagram illustrating a relationship between film thickness of a dielectric film which is made of silicon nitride and inclinations of change amounts of acoustic velocities in a central region and a low acoustic-velocity region of an IDT electrode. The inclination of a change amount of an acoustic velocity here indicates an inclination between adjacent measurement points in FIG. 5, that is, an acoustic velocity change rate. ● denotes a result in the low acoustic-velocity region and ◯ denotes a result in the central region.

As is clear from FIG. 6, the relationship between the inclination in the low acoustic-velocity region and the inclination in the central region is reversed between a region where the dielectric film thickness is less than or equal to about 1.2% and a region where the dielectric film thickness is greater than about 1.2%. That is, the inclination in the central region is greater in the region where the dielectric film thickness is less than or equal to about 1.2%. This means that the acoustic velocity change amount with respect to the dielectric film thickness is larger in the central region. Accordingly, when the thickness of the dielectric film 6 is increased, the acoustic velocity in the central region becomes higher than the acoustic velocity in the first and second low acoustic-velocity regions, thus increasing the acoustic velocity difference.

On the other hand, in the region where the dielectric film thickness is greater than about 1.2%, the inclination in the first and second low acoustic-velocity regions is larger, indicating that the acoustic velocity difference tends to become smaller.

The acoustic velocity change tendency depending on the film thickness change of the dielectric film 6 is different between the central region C and the first and second low acoustic-velocity regions E1 and E2 as described above, and therefore, the acoustic velocity ratio depending on the film thickness of the dielectric film 6 changes as shown in FIG. 4.

A sufficient acoustic velocity ratio can be achieved if the film thickness of the dielectric film 6 is greater than 0% and is less than or equal to about 3.125%, as shown in FIG. 4. Accordingly, transverse modes can be effectively reduced or prevented.

Although FIG. 4 shows the result of the dielectric film 6 that is a silicon nitride film, the dielectric film 6 may be made of other materials.

FIG. 7 is a diagram illustrating a relationship between the film thickness of the dielectric film 6 which is, for example, a silicon oxide (SiO₂) film and an acoustic velocity ratio. As is clear from FIG. 7, when the dielectric film 6 is a silicon oxide film, a sufficient acoustic velocity ratio can be obtained if the film thickness is from about 0.5% to about 3.5% inclusive. Accordingly, transverse modes can be effectively reduced or prevented.

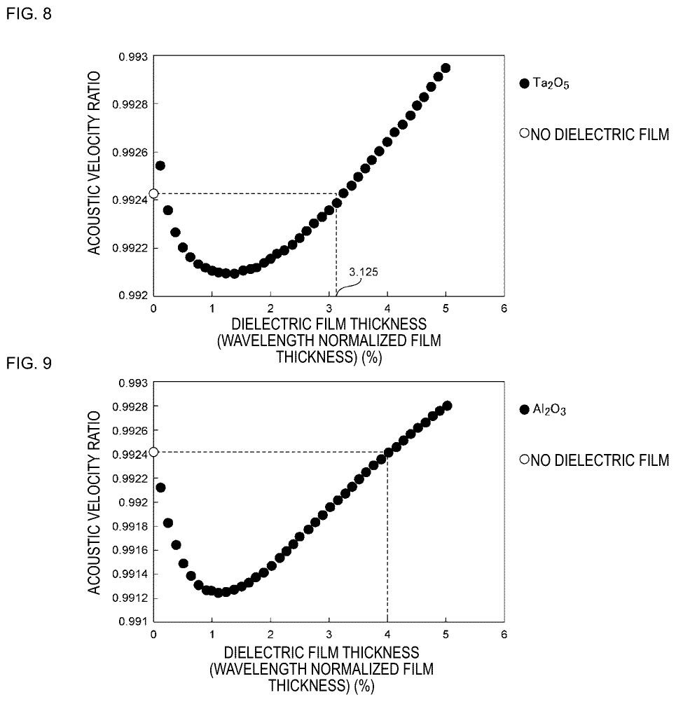

FIG. 8 is a diagram illustrating a relationship between the film thickness of the dielectric film 6 which is, for example, a tantalum pentoxide (Ta₂O₅) film and an acoustic velocity ratio. As is clear from FIG. 8, when the dielectric film 6 is a tantalum pentoxide film, a sufficiently-high acoustic velocity ratio can be obtained and transverse modes can be effectively reduced or prevented if the film thickness is greater than 0% and is less than or equal to about 3.125%.

FIG. 9 is a diagram illustrating a relationship between the film thickness of the dielectric film 6 which is, for example, an alumina (Al₂O₃) film and an acoustic velocity ratio. As is clear from FIG. 9, when the dielectric film 6 is an alumina film, a sufficiently-high acoustic velocity ratio can be obtained and transverse modes can be effectively reduced or prevented if the film thickness is greater than 0% and is less than or equal to about 4%.

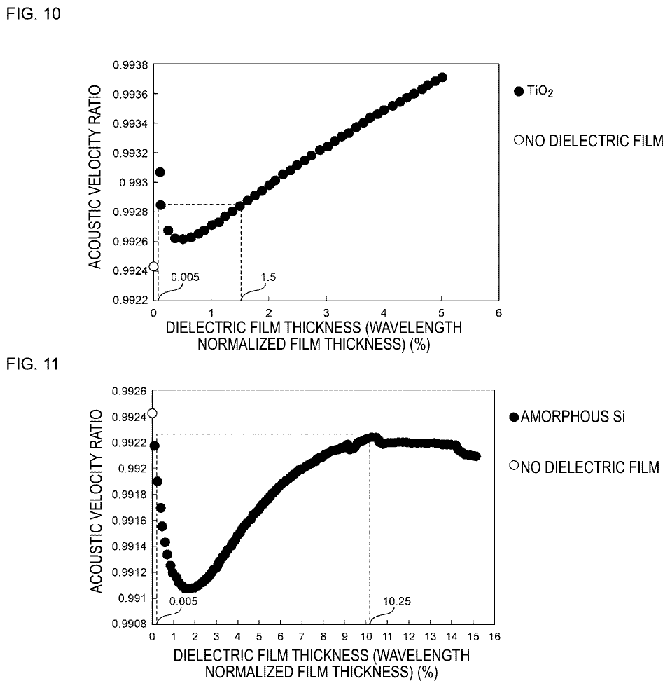

FIG. 10 is a diagram illustrating a relationship between the film thickness of the dielectric film 6 which is, for example, a titanium oxide (TiO₂) film and an acoustic velocity ratio. As is clear from FIG. 10, when the dielectric film 6 is a titanium oxide film, a sufficiently-high acoustic velocity ratio can be obtained if the film thickness is from about 0.005% to about 1.5% inclusive. Accordingly, transverse modes can be effectively reduced or prevented.

FIG. 11 is a diagram illustrating a relationship between the film thickness of the dielectric film 6 which is, for example, an amorphous silicon film and an acoustic velocity ratio. As is clear from FIG. 11, when the dielectric film 6 is an amorphous silicon film, a sufficiently-high acoustic velocity ratio can be obtained and transverse modes can be effectively reduced or prevented if the film thickness is from about 0.005% to about 10.25% inclusive.

Thus, if the film thickness of the dielectric film 6 is set in film thickness ranges shown in Table 2 below depending on a kind of each material of the dielectric film 6, transverse modes can be effectively reduced or prevented.

TABLE 2

| Material of dielectric film | Film thickness range (Unit: %) |
|---|---|
| Silicon nitride | Greater than 0, about 3.125 or less |
| Silicon oxide | From about 0.5 to about 3.5 inclusive |
| Tantalum pentoxide | Greater than 0, about 3.125 or less |
| Alumina | Greater than 0, about 4 or less |
| Titanium oxide | From about 0.005 to about 1.5 inclusive |
| Amorphous silicon | From about 0.005 to about 10.25 inclusive |

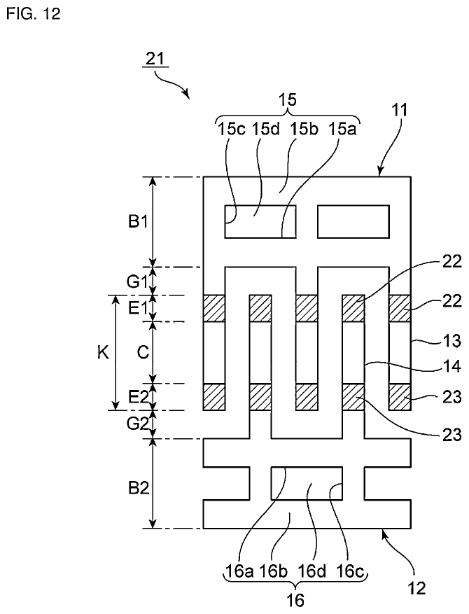

FIG. 12 is a plan view for explaining an IDT electrode of an acoustic wave device according to a second preferred embodiment of the present invention.

As illustrated in FIG. 12, in an IDT electrode 21 of the acoustic wave device according to the second preferred embodiment, mass addition films 22 and 23 are provided on the first and second electrode fingers 13 and 14 in the first and second low acoustic-velocity regions E1 and E2. The mass addition films 22 and 23 are made of, for example, metal. However, the mass addition films 22 and 23 may be made of a material other than metal. The provision of the mass addition films 22 and 23 lowers the acoustic velocity in the first and second low acoustic-velocity regions E1 and E2.

FIG. 13 is a plan view for explaining an IDT electrode 31 of an acoustic wave device according to a third preferred embodiment of the present invention. In the IDT electrode 31, wider portions 32 and 33 are provided in the first and second low acoustic-velocity regions E1 and E2 in the first and second electrode fingers 13 and 14. The width of the wider portions 32 and 33 is larger than the width in the central region C. Here, the width indicates dimensions of the first and second electrode fingers 13 and 14 along the acoustic wave propagating direction. Thus, the acoustic velocity may be lowered by providing the wider portions 32 and 33 in the first and second low acoustic-velocity regions E1 and E2.

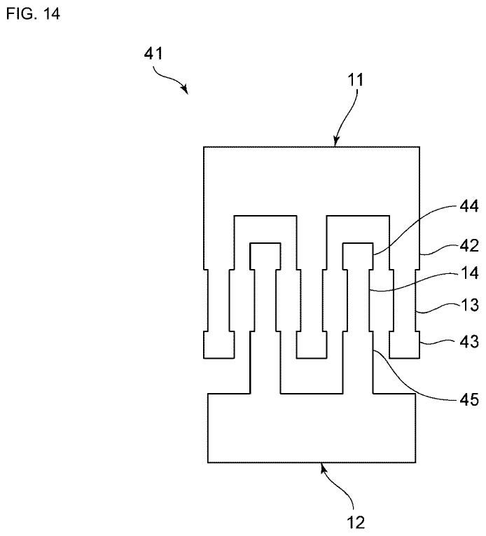

FIG. 14 is a plan view for explaining an IDT electrode 41 of an acoustic wave device according to a fourth preferred embodiment of the present invention. In the IDT electrode 41, wider portions 42 and 43 are provided in the first and second low acoustic-velocity regions in the first electrode fingers 13. In a similar manner, wider portions 44 and 45 are provided in the second electrode fingers 14. The difference from the IDT electrode 31 is that the wider portion 42 is provided, not only in the first low acoustic-velocity region, over the first gap region in the first electrode fingers 13. In a similar manner, the wider portion 45 is also provided over the second gap region in the second electrode fingers 14. In such a structure as well, the acoustic velocity in the first and second low acoustic-velocity regions can be set lower than the acoustic velocity in the central region and the acoustic velocity in the first and second gap regions can be set higher than the acoustic velocity in the first and second low acoustic-velocity regions.

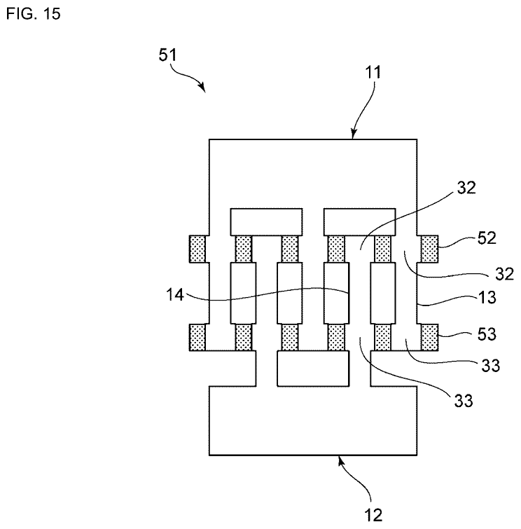

FIG. 15 is a plan view for explaining an IDT electrode 51 of an acoustic wave device according to a fifth preferred embodiment of the present invention. In the IDT electrode 51, the wider portions 32 and 33 are provided in the first and second low acoustic-velocity regions as is the case with the IDT electrode 31. In addition to this, dielectric films 52 and 53 are laminated under the first and second electrode fingers 13 and 14 in the first and second low acoustic-velocity regions, in the IDT electrode 51. The dielectric films 52 and 53 extend not only under the wider portions 32 and 33 but also in a region between adjacent first and second electrode fingers 13 and 14. That is, the dielectric films 52 and 53 are provided to extend in the acoustic wave propagating direction. However, the dielectric films 52 and 53 may be positioned only under the wider portions 32 and 33.

In the IDT electrode 51, the provision of the dielectric films 52 and 53 in addition to the wider portions 32 and 33 can more effectively lower the acoustic velocity in the first and second low acoustic-velocity regions.

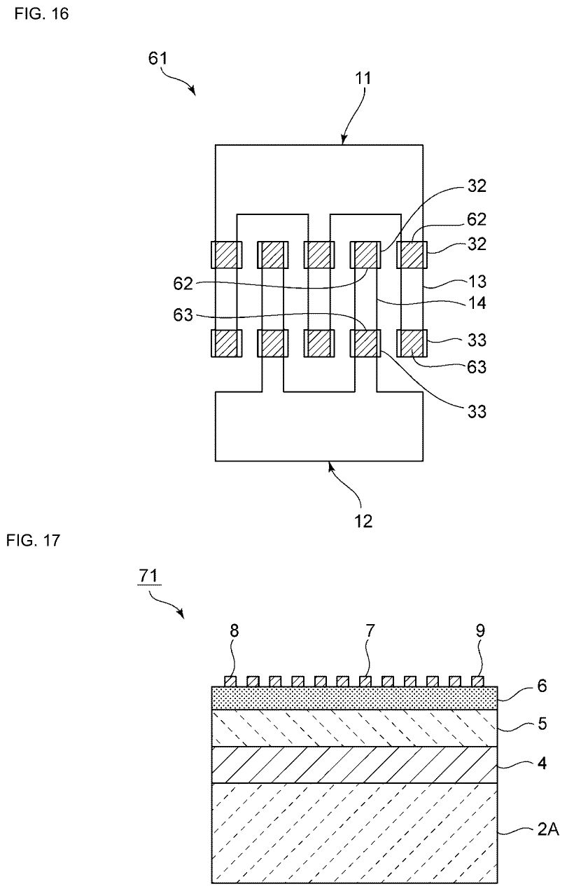

FIG. 16 is a plan view for explaining an IDT electrode 61 of an acoustic wave device according to a sixth preferred embodiment of the present invention. In the IDT electrode 61, the wider portions 32 and 33 are provided in the first and second low acoustic-velocity regions. In addition to this, mass addition films 62 and 63 are laminated on the first and second electrode fingers 13 and 14 in the first and second low acoustic-velocity regions. The mass addition films 62 and 63 are made of, for example, metal in the present preferred embodiment, but a dielectric material may be used. Further, the widths of the mass addition films 62 and 63 may be equal or substantially equal to those of the wider portions 32 and 33 or the mass addition films 62 and 63 may have narrower widths than the wider portions 32 and 33.

In the IDT electrode 61, the above-described mass addition films 62 and 63 are provided in addition to the wider portions 32 and 33. Accordingly, the acoustic velocity in the first and second low acoustic-velocity regions can be more effectively lowered.

As illustrated in FIGS. 12 to 16, the structure for setting the acoustic velocity in the first and second low acoustic-velocity regions lower than the acoustic velocity in the central region is not particularly limited and various structures can be used, in the acoustic wave devices according to preferred embodiments of the present invention. Further, the first and second busbars may be structured to include an inner busbar, an outer busbar, a coupling portion, and an opening as the structure illustrated in FIG. 3, in the IDT electrodes illustrated in FIGS. 13 to 16.

FIG. 17 is a front sectional view of an acoustic wave device according to a seventh preferred embodiment of the present invention. In an acoustic wave device 71, the low acoustic-velocity film 4 and the piezoelectric film 5 are laminated on a support substrate 2A. That is, the high acoustic-velocity material layer 3 illustrated in FIGS. 1A and 1B is used. Here, the support substrate 2A is made of a high acoustic-velocity material in the acoustic wave device 71. That is, the support substrate 2A corresponds to a structure in which the support substrate 2 illustrated in FIGS. 1A and 1B and the high acoustic-velocity material layer 3 are integrated with each other. Thus, when the support substrate 2A made of a high acoustic-velocity material is used, the high acoustic-velocity material layer 3 may be omitted. Further, the low acoustic-velocity film 4 may be omitted in the acoustic wave devices 1 and 71. In other words, the piezoelectric film 5 may be directly laminated on the high acoustic-velocity material layer 3 or the support substrate 2A made of a high acoustic-velocity material.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a high acoustic-velocity material layer made of a high acoustic-velocity material;
a piezoelectric film directly or indirectly provided on the high acoustic-velocity material layer; and
an IDT electrode on the piezoelectric film; wherein
the high acoustic-velocity material is a material in which an acoustic velocity of a bulk wave propagating therethrough is higher than an acoustic velocity of an acoustic wave propagating through the piezoelectric film;
the acoustic wave device further includes a dielectric film between the IDT electrode and the piezoelectric film;
the IDT electrode includes a first electrode finger and a second electrode finger that are interdigitated, a direction orthogonal or substantially orthogonal to an extending direction of the first electrode finger and the second electrode finger is an acoustic wave propagating direction, a region in which the first electrode finger and the second electrode finger overlap with each other when viewed in the acoustic wave propagating direction is an intersecting region, and the intersecting region includes a central region positioned in a center in the extending direction of the first electrode finger and the second electrode finger, and first and second low acoustic-velocity regions on both respective sides of the central region in the extending direction of the first electrode finger and the second electrode finger; and
the dielectric film is made of silicon nitride, silicon oxide, tantalum pentoxide, alumina, titanium oxide, or amorphous silicon, and a film thickness of the dielectric film is set in a range shown in Table 1 below depending on a material of the dielectric film:
TABLE 1

| Material of dielectric film | Film thickness range (Unit: %) |
|---|---|
| Silicon nitride | Greater than 0, about 3.125 or less |
| Silicon oxide | From about 0.5 to about 3.5 inclusive |
| Tantalum pentoxide | Greater than 0, about 3.125 or less |
| Alumina | Greater than 0, about 4 or less |
| Titanium oxide | From about 0.005 to about 1.5 inclusive |
| Amorphous silicon | From about 0.005 to about 10.25 inclusive |

where the film thickness in Table 1 is a film thickness (%) normalized by a wavelength A determined based on an electrode finger pitch of the IDT electrode.

2. The acoustic wave device according to claim 1, wherein a width in the first and second low acoustic-velocity regions of the first electrode finger and the second electrode finger along the acoustic wave propagating direction is larger than a width of the first electrode finger and the second electrode finger in the central region.

3. The acoustic wave device according to claim 1, further comprising a mass addition film laminated on the first electrode finger and the second electrode finger in the first and second low acoustic-velocity regions.

4. The acoustic wave device according to claim 3, wherein the mass addition film is made of a dielectric material.

5. The acoustic wave device according to claim 3, wherein the mass addition film is made of metal.

6. The acoustic wave device according to claim 1, further comprising a support substrate laminated on a surface of the high acoustic-velocity material layer opposite to a surface on a piezoelectric film side.

7. The acoustic wave device according to claim 6, wherein
the support substrate is made of the high acoustic-velocity material; and
the support substrate and the high acoustic-velocity material layer are integrated with each other.

8. The acoustic wave device according to claim 6, further comprising:
a low acoustic-velocity film laminated between the high acoustic-velocity material layer and the piezoelectric film and being made of a low acoustic-velocity material; wherein
the low acoustic-velocity material is a material in which an acoustic velocity of a bulk wave propagating therethrough is lower than an acoustic velocity of a bulk wave propagating through the piezoelectric film.

9. The acoustic wave device according to claim 6, wherein the support substrate is made of Si.

10. The acoustic wave device according to claim 1, wherein the high acoustic-velocity material layer is silicon nitride.

11. The acoustic wave device according to claim 8, wherein the low acoustic-velocity material layer is made of silicon oxide.

12. The acoustic wave device according to claim 1, wherein the piezoelectric film is made of lithium tantalate.

13. The acoustic wave device according to claim 1, wherein the IDT electrode includes a first busbar connected to the first electrode finger, and a second busbar connected to the second electrode finger.

14. The acoustic wave device according to claim 13, wherein each of the first and second busbars includes an inner busbar, an outer busbar, and a coupling portion coupling the inner busbar and the outer busbar.

15. The acoustic wave device according to claim 14, wherein each of the first and second busbars includes at least one opening extending along the acoustic wave propagation direction.
